(19) United States
(12) Patent Application Publication
(10) Pub. No.: US 2024/0213091 A1
(43) Pub. Date: Jun. 27, 2024

(54) METHOD FOR PRODUCING A SEMICONDUCTIVE DEVICE COMPRISING A BACK GATE

(71) Applicant: COMMISSARIAT A L'ENERGIE ATOMIQUE ET AUX ENERGIES ALTERNATIVES, Paris (FR)

(72) Inventors: Heimanu NIEBOJEWSKI, Grenoble Cedex 09 (FR); Thomas BEDECARRATS, Grenoble Cedex 09 (FR); Benoit BERTRAND, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/394,546

(22) Filed: Dec. 22, 2023

(30) Foreign Application Priority Data
Dec. 23, 2022 (FR) 22 14382

(51) Int. Cl. H01L 21/768; H01L 21/762; H01L 29/423; H01L 29/66

(52) U.S. Cl. CPC H01L 21/76877; H01L 21/76229; H01L 21/76831; H01L 29/4236; H01L 29/66977

(57) ABSTRACT

A method is provided for producing a back gate under a semiconductive device surrounded by isolation trenches. The method includes a partial etching of the isolation trenches forming an opening to the sacrificial layer, a selective removal of the sacrificial layer forming a cavity under the device, and a filling of the cavity with a conductive material so as to form the back gate. Advantageously, the formation of the isolation trenches comprises a formation of a sacrificial coating layer at the flanks of the trenches, in contact with the sacrificial layer, before filling with an isolating material, and the partial etching of the trenches comprises a removal of this sacrificial coating layer selectively at the isolating material.

### TECHNICAL FIELD

The present invention relates to the field of microelectronic and quantum electronics, in particular. It has, for example, a particularly advantageous application for producing back gates in quantum devices with quantum bits (called qubits), in particular for devices based on spin qubit or supraconductive qubit architectures.

### PRIOR ART

Semiconductive devices, for example, transistors, integrated on a silicon on isolator (SOI) semiconductor-type substrate, generally have better performance than semiconductive devices integrated on a bulk substrate, in particular at the end of consumption. To improve the electrostatic control of these on-SOI integrated semiconductive devices, a conductive back gate can be formed under the buried isolator layer, preferably in vertical alignment with the active zone of the semiconductive device, which is formed in the superficial semiconductive layer located on the buried isolator layer. An electric contact on this back gate makes it possible to apply a variable voltage to the back gate and to thus modulate the electrostatic environment at the active zone of the semiconductive device.

For quantum applications, in particular, this back gate voltage is an additional parameter which is very useful for modulating the electrostatic environment of the quantum points.

To produce this conductive back gate, “back face” methods are complex and invasive, and not very suitable for the scale of a full wafer. Alternatively, front face ion implantation methods, which make it possible to very highly dope the substrate under the buried isolator layer, induce residual dopants in the superficial semiconductive layer. These residual dopants are not, in particular, compatible with the operation of quantum points.

Document FR2952472A1 describes an example of a method for producing a back gate under an on-SOI semiconductive device. In this example, each device is electrically isolated by isolation trenches passing through the superficial semiconductive layer and the buried isolator layer, and extending to the substrate. The method consists of forming an opening within an isolation trench by anisotropic etching, then extend this isotropic etching such that the opening opens into the buried isolator layer, under the superficial semiconductive layer. A removal of the material of the buried isolator layer, selectively at the materials of the substrate, from the superficial semiconductive layer and from the isolation trenches, is thus done through the opening. A cavity is thus formed under the semiconductive device. The cavity is then filled with a conductive material, so as to form the conductive back gate under the semiconductive device. The opening is also filled with the conductive material and thus forms an electric contact for the back gate. A disadvantage of this method, is that the opening made within the isolation trench is relatively wide, which limits the integration density of the devices. The minimum width to be provided for these isolation trenches must be relatively high to enable the formation of a back gate locally, under an individual device, without impacting the integrity of a neighbouring device.

Therefore, there remains a need to have a method for producing a back gate under an on-SOI semiconductive device, enabling a larger integration density. An aim of the invention is to respond to this need, and to overcome at least partially the disadvantages of the known solutions.

In particular, an aim of the invention is a method for producing a back gate under an on-SOI semiconductive device making it possible to increase the integration density. Another aim of the invention is a device coming from such a production method.

Other aims, features and advantages of the present invention will appear upon examining the description below and the accompanying drawings. It is understood that other advantages can be incorporated.

### SUMMARY

To achieve this aim, according to an embodiment, a method for producing a back gate under a semiconductive device is provided, said semiconductive device being formed on or from a semiconductive layer of a stack successively comprising a support layer, a sacrificial layer and the semiconductive layer.

The method comprises:
a formation of isolation trenches around the semiconductive device, said isolation trenches passing through the superficial semiconductive layer and the sacrificial layer, and extending to the support layer,
a partial etching of the isolation trenches so as to form an opening, opening onto the sacrificial layer,
a removal of the sacrificial layer selectively at the semiconductive layer, to the support layer and to the isolation trenches, so as to form a cavity under the semiconductive device,
a filling of the cavity with an electrically conductive material, so as to form the back gate under the semiconductive device.

Advantageously, the formation of the isolation trenches comprises:
a first etching configured to form at least one trench pattern having a bottom and flanks,
a formation of a sacrificial covering layer at least on the flanks of the at least one trench pattern, in contact with the sacrificial layer of the stack, then
a filling of the at least one trench pattern with an isolating material, configured such that said isolating material extends at least within the sacrificial layer of the stack, and preferably to within the support layer of the stack.

Advantageously, the partial etching of the isolation trenches comprises:
a removal of the sacrificial coating layer selectively at the isolating material.

Thus, only one part localised on the flanks of the trench pattern is etched during the partial etching of the isolation trench. This makes it possible to confine the partial etching between the flank of the trench pattern and the isolating material for filling the isolation trench.

Contrary to the solution disclosed by document FR 2952472 A1 wherein the partial etching of the isolation trench is not confined, the sizing of the isolation trench is thus better controlled. This makes it possible to increase the integration density of the semiconductive devices.

It is further possible to perform a partial etching of the isolation trench at one single flank of the trench pattern. This makes it possible to access a sacrificial layer located on the side of this flank only, by preserving the other flank of the trench pattern. Different semiconductive devices can thus be cointegrated, densely and easily. In particular, a semiconductive device comprising a back gate can be formed directly in the vicinity of a semiconductive device without a back gate, without it being necessary to increase the width of the isolation trench, separating them from one another, contrary to the solution disclosed by document FR 2952472 A1. The method according to the invention thus offers an improved solution for the production of back gates localised under one or more semiconductive devices, with an increased integration density.

Another aspect of the invention relates to a semiconductive device comprising a back gate formed by the method, according to the invention.

### BRIEF DESCRIPTION OF THE FIGURES

The aims, objectives, as well as the features and advantages of the invention will best emerge from the detailed description of an embodiment of the latter, which is illustrated by the following accompanying drawings, wherein:

FIGS. 1A, 2A, 3A, 4A, 5A, 6A, 7A, 8A, 9A, 10A, 11A, 12A, 13A, 14A, 15A, 16A, 17A schematically illustrate, as a cross-section, steps of manufacturing a back gate under a semiconductive device, according to an embodiment of the present invention.

FIGS. 1B, 2B, 3B, 4B, 5B, 6B, 7B, 8B, 9B, 10B, 11B, 12B, 13B, 14B, 15B, 16B, 17B schematically illustrate, as a top view, the manufacturing steps illustrated in corresponding FIGS. 1A, 2A, 3A, 4A, 5A, 6A, 7A, 8A, 9A, 10A, 11A, 12A, 13A, 14A, 15A, 16A, 17A, according to an embodiment of the present invention.

FIGS. 4C, 4D, 4E schematically illustrate, as a cross-section, steps of manufacturing an isolation trench, according to another embodiment of the present invention.

FIG. 17C schematically illustrates, as a cross-section, a semiconductive device comprising a back gate, adjacent to another semiconductive device without a back gate, according to an embodiment of the present invention.

The drawings are given as examples and are not limiting of the invention. They constitute principle schematic representations, intended to facilitate the understanding of the invention and are not necessarily to the scale of practical applications. In particular, on the principle diagrams, the thicknesses and/or the dimensions of the different layers, patterns and raised parts are not representative of reality. For reasons of clarity, all the alphanumeric references are not systematically repeated from one figure to the other. It is understood that the elements already described and referenced, when they are reproduced in another figure, typically have the same alphanumeric references, even if these are not explicitly mentioned, a person skilled in the art will identify, without difficulties, one same element reproduced in different figures.

### DETAILED DESCRIPTION

Before starting a detailed review of embodiments of the invention, optional features are stated below, which can optionally be used in association or alternatively:

According to an example, the semiconductive device is a quantum device and the electrically conductive material is metal. A conductive metal material makes it possible to obtain a back gate, which is operational even at a low temperature, typically for operating temperatures of a quantum device. Contrary to a doped or highly doped-type semiconductive-type conductive material, a metal material is not sensitive to the gel of the carriers which occurs at a low temperature. The metal back gate thus remains operational at a low temperature.

According to an example, the semiconductive device is adjacent to a second semiconductive device separated from the semiconductive device by an isolation trench having a first flank on the side of the semiconductive device and a second flank on the side of the second semiconductive device, said isolation trench comprising a first sacrificial coating layer portion on the first flank and a second sacrificial coating layer portion on the second flank.

According to an example, the partial etching of said isolation trench comprises a simultaneous removal of the first and second sacrificial coating layer portions, so as to form a first back gate under the semiconductive device and a second back gate under the second semiconductive device. The method thus makes it possible to simultaneously form several back gates for adjacent devices, by preserving an operational isolation trench between the adjacent devices, thanks to the isolating material inserted between the first and second sacrificial coating layer portions in the isolation trench.

According to an alternative example, the partial etching of said isolation trench comprises a removal of the first sacrificial coating layer portion only, without removal of the second sacrificial coating layer portion, so as to form the back gate only under the semiconductive device, by preserving a sacrificial layer portion under the second semiconductive device. The method thus makes it possible to form a back gate for only one of the adjacent devices, by preserving an operational isolation trench between the adjacent devices, thanks to the isolating material and to the second sacrificial coating layer portion in the isolation trench.

According to an example, the formation of the sacrificial coating layer is done by compatible deposition on the flanks and the bottom of the at least one trench pattern.

According to an example, the removal of the sacrificial coating layer is only partial and configured to preserve a portion of the sacrificial coating layer located on the bottom of the at least one trench pattern. The number of steps of the method for forming the isolation trench and the openings to the sacrificial layer is thus limited.

According to an example, the formation of the sacrificial coating layer comprises a compatible deposition on the flanks and the bottom of the at least one trench pattern, followed by an anisotropic etching configured to remove a portion of the sacrificial coating layer located on the bottom of the at least one trench pattern, such that the sacrificial coating layer only covers the flanks of the at least one trench pattern, before filling the at least one trench pattern with the isolating material.

According to an example, the removal of the sacrificial coating layer is total. The formation of the openings to the sacrificial layer is thus facilitated. It is not necessary to specifically control the stopping of etching during the removal of the sacrificial coating layer.

According to an example, the sacrificial coating layer is chosen with the basis of a first dielectric material, for example, SiN or SiC. This makes it possible to preserve sacrificial coating layer portions in the isolation trench without weakening or compromising the isolation function of the isolation trench.

According to an example, the formation of the sacrificial coating layer is configured, such that the sacrificial coating layer has a thickness e₁₅ in a direction transverse to the flanks of the at least one trench pattern, and the filling of the at least one trench pattern by the isolating material is configured, such that the isolating material has a thickness e16 in said transverse direction, such that e₁₅<e₁₆/3. This makes it possible to size the isolation trench according to proportions balancing the isolation function by the isolating material and the function of access to the sacrificial layer of the stack by the sacrificial coating layer. The isolation between adjacent devices and the access to the sacrificial layer of the stack are thus optimised.

According to an example, the method further comprises after removal of the sacrificial layer and before filling the cavity with an electrically conductive material, a compatible deposition of a layer made of a second dielectric material on exposed walls of the cavity, for example, by chemical vapour deposition (CVD). This makes it possible to insulate the back gate with respect to the support layer and/or with respect to the superficial semiconductive layer.

According to an example, the layer made of a second dielectric material has a thickness e₅₁, the sacrificial coating layer has a thickness e₁₅, the electrically conductive material has a thickness e₅, such that e₅₁<e₁₅/3 and e₅₁<e₅/3, and preferably such that e₅₁<e₁₅/4 and e₅₁<e₅/4. This makes it possible to size the back gate and the contact via on this back gate according to balanced proportions. The bias of the back gate and the isolation of the back gate with respect to the support layer and/or with respect to the superficial semiconductive layer are thus optimised.

According to an example, the isolating material of the isolation trenches is chosen with the basis of SiO₂. The isolating material of the isolation trenches is different from the first dielectric material of the sacrificial coating layer.

According to an example, the first dielectric material of the sacrificial coating layer has, with respect to the isolating material of the isolation trenches, a selectivity to the etching S≥5:1.

According to an example, the sacrificial layer is formed on the support layer by epitaxy, said sacrificial layer being, for example, SiGe-based.

Unless incompatible, it is understood that all the optional features above can be combined, so as to form an embodiment, which is not necessarily illustrated or described. Such an embodiment is clearly not excluded from the invention. The features and the advantages of an aspect of the invention, for example, the device or the method, can be adapted mutatis mutandis to the other aspect of the invention.

The invention is generally based on a method for manufacturing a back gate for a semiconductive device, and on such a device equipped with a back gate. This back gate can also be called back electrode. A semiconductive device according to the invention typically comprises a semiconductive layer, wherein charge carriers or quantum states travel and/or are confined. For example, and in a non-limiting manner, this semiconductive layer can thus form a transistor channel, or be integrated in a spin qubit architecture for quantum devices with quantum bits (called qubits).

It is specified that, in the scope of the present invention, the terms “on”, “surmounts”, “covers”, “underlying”, “opposite” and their equivalents do not necessarily mean “in contact with”. Thus, for example, the deposition, the transfer, the adhering, the assembly or the application of a first layer on a second layer, does not compulsorily mean that the two layers are directly in contact with one another, but means that the first layer covers at least partially the second layer, by being either directly in contact with it, or by being separated from it by at least one other layer or at least one other element.

By a substrate, a film, a layer, “with the basis” of a material A, this means a substrate, a film a layer comprising this material A only, or this material A and optionally other materials, for example doping elements or alloy elements.

Several embodiments of the invention implementing successive steps of the manufacturing method are described below. Unless explicitly mentioned, the adjective “successive” does not necessarily imply, even if this is generally preferred, that the steps follow one another immediately, intermediate steps being able to separate them.

Moreover, the term “step” means the carrying out of a part of the method, and can mean a set of substeps.

Moreover, the term “step” does not compulsorily mean that the actions carried out during a step are simultaneous or immediately successive. Certain actions of a first step can in particular be followed by actions linked to a different step, and other actions of the first step can then be resumed. Thus, the term “step” does not necessarily mean single and inseparable actions over time and in the sequence of phases of the method.

By “selective etching with respect to” or “etching having a selectivity with respect to”, this means an etching configured to remove a material A or a layer A with respect to a material B or a layer B, and having an etching speed of the material A greater than the etching speed of the material B. The selectivity is the ratio between the etching speed of the material A over the etching speed of the material B. It is referenced S_{A:B}. A selectivity S_{A:B} of 10:1 means that the etching speed of the material A is 10 times greater than the etching speed of the material B.

By “extends within” a layer, this means the action of penetrating into this layer, directly or indirectly. In particular, a structure or a material extending within a layer means that the structure or the material are extended between the two faces defining said layer, typically between the two upper and lower faces. Thus, a filling material which extends at least to within the sacrificial layer of the stack means that the filling material has a portion or a lower face located between the planes defined by the upper and lower faces of the sacrificial layer of the stack. A filling material which extends at least to within the support layer of the stack means that the filling material has a portion or a lower face located between the planes defined by the upper and lower faces of the support layer of the stack. In this case, a filling material extending to within the support layer totally passes through the sacrificial layer of the stack. This makes it possible to facilitate the isolation between two adjacent devices during the etching of the sacrificial coating layer followed by the filling of the cavity by an electrically conductive material to form the back gate(s) under one and/or the other of the adjacent devices. The tolerance on stopping the etching of the sacrificial coating layer is increased.

A preferably orthonormal system, comprising the axes x, y, z is represented in the accompanying figures. When one single system is represented in one same set of figures, this system applies to all the figures of this set.

In the present patent application, thickness will preferably be referred to, for a layer or a film, and height for a device or a structure. The thickness is taken in a direction normal to the main extension plane of the layer or of the film. Thus, an epitaxially grown superficial silicon layer typically has a thickness along z. A gate pattern formed on such a superficial layer has a height along z. The relative terms “on”, “surmounts”, “under”, “underlying” refer to positions taken in the direction z. A“lateral” dimension corresponds to a dimension in a direction of the plane xy. By a “lateral” extension or “laterally” means, an extension in one or more directions of the plane xy. The thicknesses e₁₅, e₁₆, e₅₁, e₅, etc. of the different layers are, naturally, strictly positive.

An element located “in vertical alignment with” or “to the right” of another element means that these two elements are both located on one same line perpendicular to a plane, wherein a lower or upper face of a substrate mainly extends, i.e. on one same line oriented vertically in the figures, as a cross-section.

The terms “substantially”, “about”, “around” mean close to 10%, and preferably close to 5%. Moreover, the terms “comprised between . . . and . . . ” and equivalent mean that the limits are inclusive, unless mentioned otherwise.

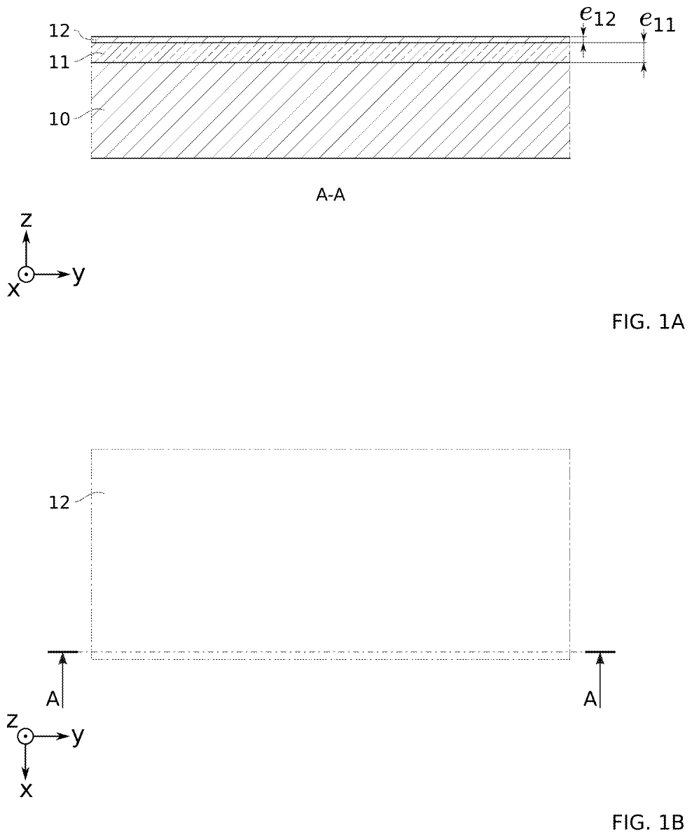

FIGS. 1A, 2A, 3A, 4A, 5A, 6A, 7A, 8A, 9A, 10A, 11A, 12A, 13A, 14A, 15A, 16A, 17A schematically illustrate, as a cross-section, steps of manufacturing a back gate under a semiconductive device, according to an embodiment. FIGS. 1B, 2B, 38, 4B, 5B, 6B, 7B, 8B, 9B, 10B, 11B, 12B, 13B, 14B, 15B, 16B, 17B schematically illustrates, as a top view, the manufacturing steps illustrated in corresponding FIGS. 1A, 2A, 3A, 4A, 5A, 6A, 7A, 8A, 9A, 10A, 11A, 12A, 13A, 14A, 15A, 16A, 17A.

As illustrated in FIGS. 1A, 1B, the first steps consist of forming, in a known manner, a stack comprising a support layer 10, typically a so-called “bulk” silicon substrate, a sacrificial layer 11, for example, an epitaxially grown SiGe layer having a germanium atomic concentration of around 20% to 30%, and a superficial semiconductive layer 12, for example, a so-called topSi epitaxially grown silicon layer below. The sacrificial layer 11 typically has a thickness e₁₁ of around 5 nm to 50 nm. The topSi layer 12 typically has a thickness e₁₂ of around 5 nm to 20 nm.

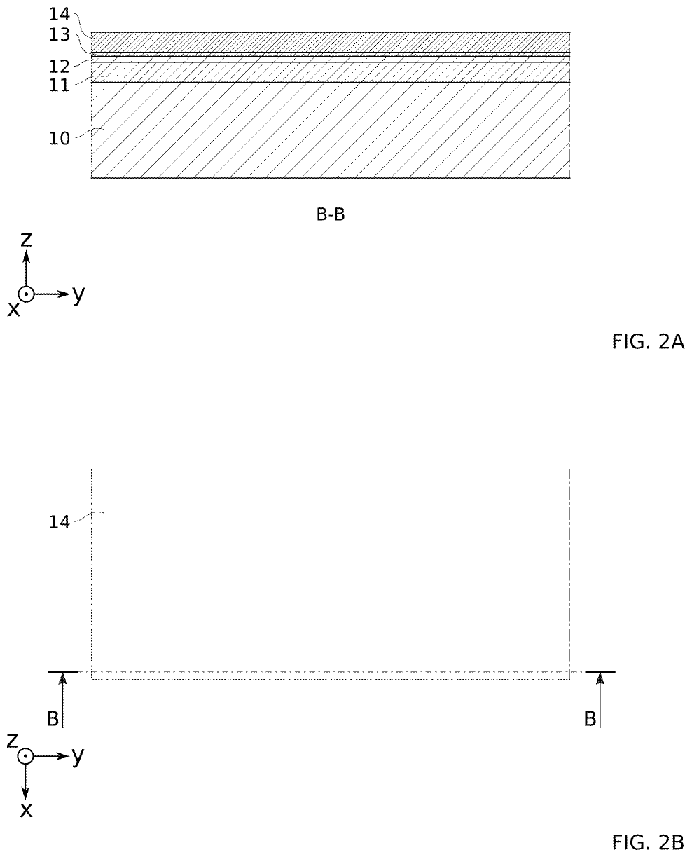

As illustrated in FIGS. 2A, 2B, a hard mask typically comprising an SiO₂-based layer 13 and an SiN-based layer 14. The layer 13 can be a PADOX (PAD OXide)-type layer, an acronym which is well-known to a person skilled in the art. The layer 13 has, for example, a thickness of around 5 nm. The layer 14 has, for example, a thickness of around 30 nm. This hard mask is typically structured and used for the etching of patterns defined by lithography.

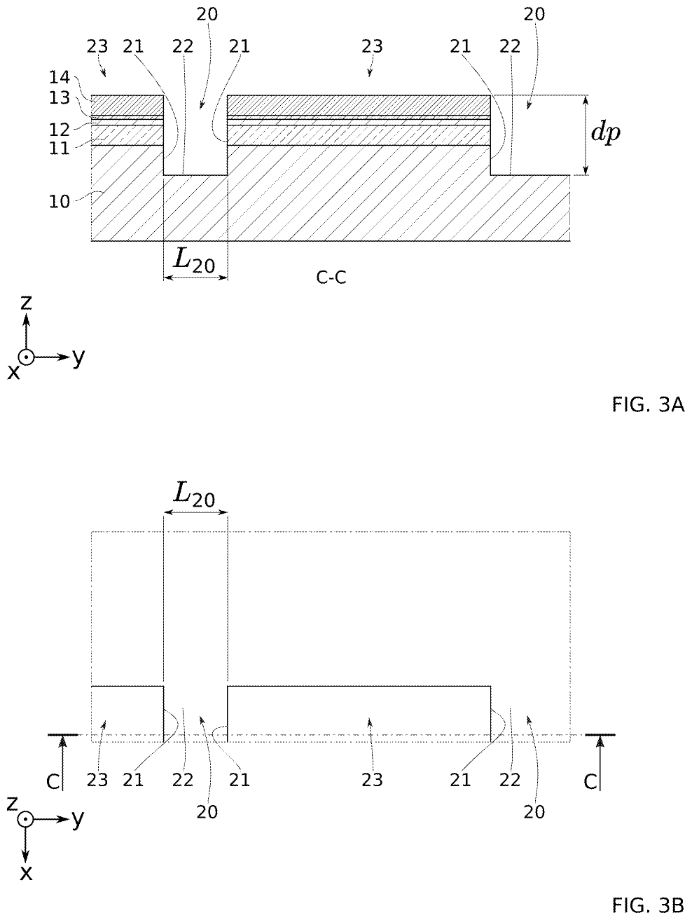

As illustrated in FIGS. 3A, 3B, after definition by lithography of the patterns 20, 23 corresponding respectively to the trench patterns 20 and to the device patterns 23, an anisotropic dry etching along z is performed. The etching depth dp is chosen so as to form the trench patterns 20 within the support layer 10, through the layers 11, 12 of the stack. The etching depth dp is, for example, of around 200 nm. A reactive ion etching (RIE) or a fluorocarbon species-based plasma etching can be used to successively etch the layers 12, 11 and 10 of the stack. Trench patterns 20 having flanks 21 and a bottom 22 are thus formed. These trench patterns 20 have a dimension by width along y L₂₀.

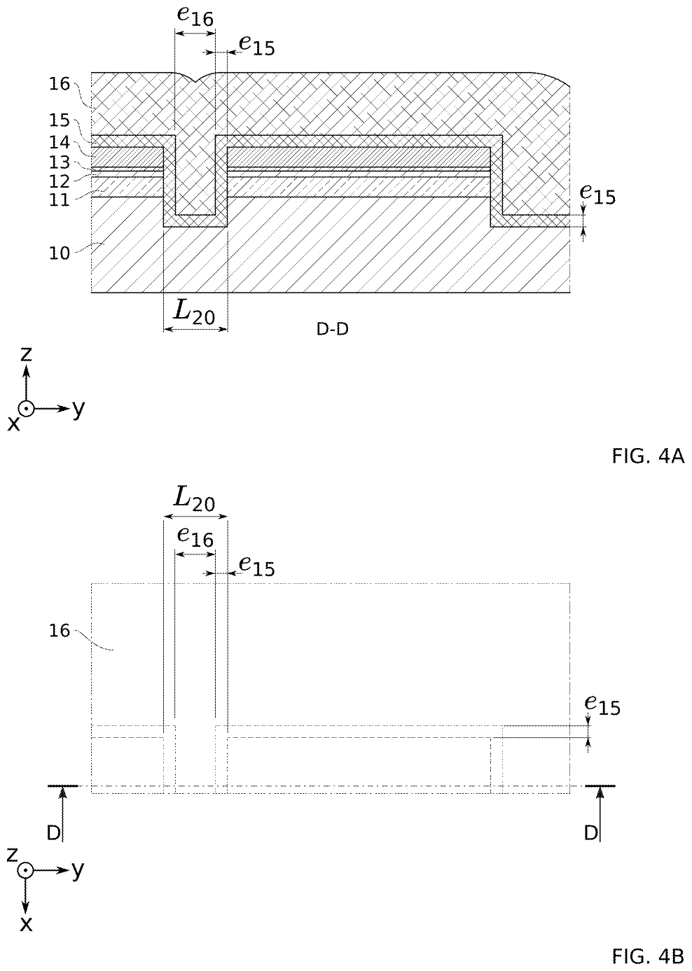

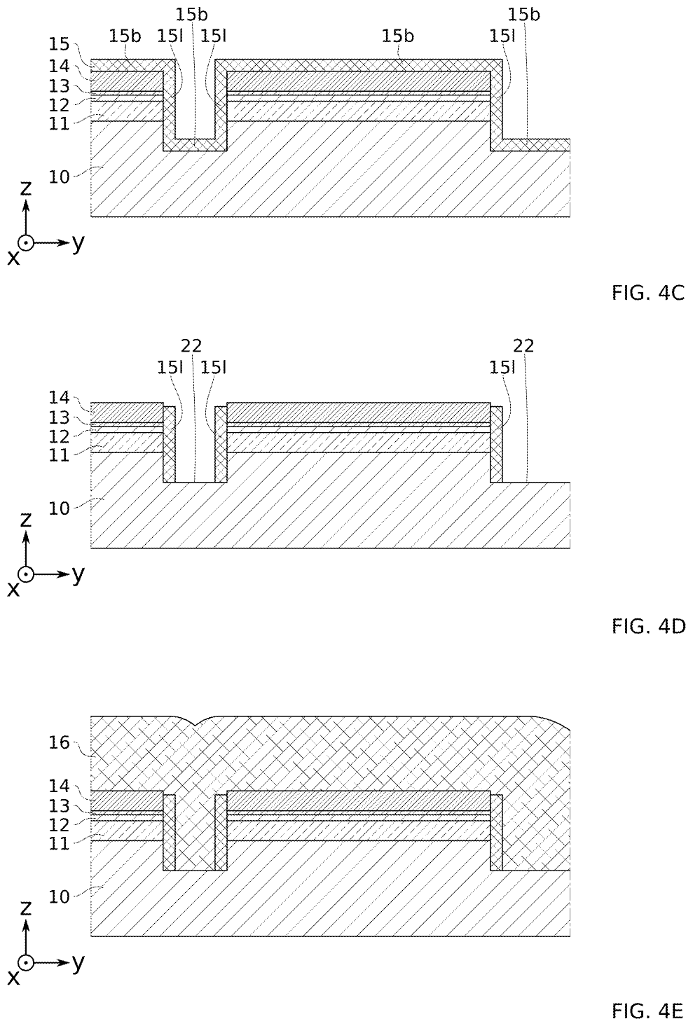

As illustrated in FIGS. 4A, 4B, a compatible deposition of a sacrificial coating layer 15 is first performed, for example, by chemical vapour deposition CVD. The layer 15 typically has a thickness e₁₅ of around 10 nm to 20 nm. According to a preferred option, the thickness e₁₅ is chosen such that e₁₅≤L₂₀/3. The sacrificial coating layer 15 is preferably with the basis of a dielectric material, for example, SiN or SiC. According to an option illustrated in FIGS. 4A, 4B, after compatible deposition of the sacrificial coating layer 15, a filling of trench patterns 20 with an isolating material 16 is then performed. The isolating material 16 is typically SiO₂-based. The filling can be performed usually by compatible deposition of the high density plasma (HDP) type, or of the flowable chemical vapour deposition (FCVD) type, or a combination of these. According to an option, the lateral dimensions along y e₁₅ and e₁₆ are such that e₁₅≤e₁₆/3.

According to another option illustrated in FIGS. 4C, 4D, 4E, after compatible deposition of the sacrificial coating layer 15 (FIG. 4C), the basal portions 15b of the layer 15 are removed by anisotropic etching along z. The bottom 22 of the trench patterns is thus exposed and while the flanks 21 of the trench patterns are covered by the lateral portions 15l of the layer 15 (FIG. 4D). The filling of the trench patterns 20 with the isolating material 16 is then performed as above (FIG. 4E).

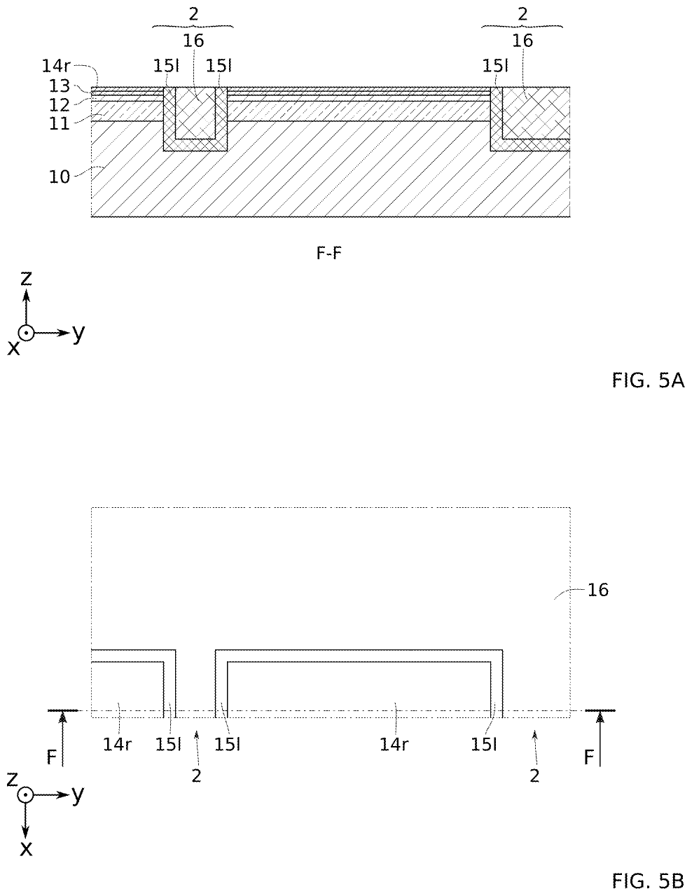

As illustrated in FIGS. 5A, 5B, after filling, a planarisation step, typically by chemical-mechanical polishing CMP, is carried out. This planarisation step aims to remove the excess isolating material 16 to form the upper face of the isolation trenches 2. The CMP polishing is typically configured to stop in the hard mask layer 14, by leaving a residual film 14r. Isolation trenches 2 of the STI (shallow trench isolation) type, comprising sacrificial coating layer portions 15 at least on the flanks 21 or on the flanks 21 and on the bottom 22 (as illustrated in FIG. 5A), and an isolating core 16, are thus formed.

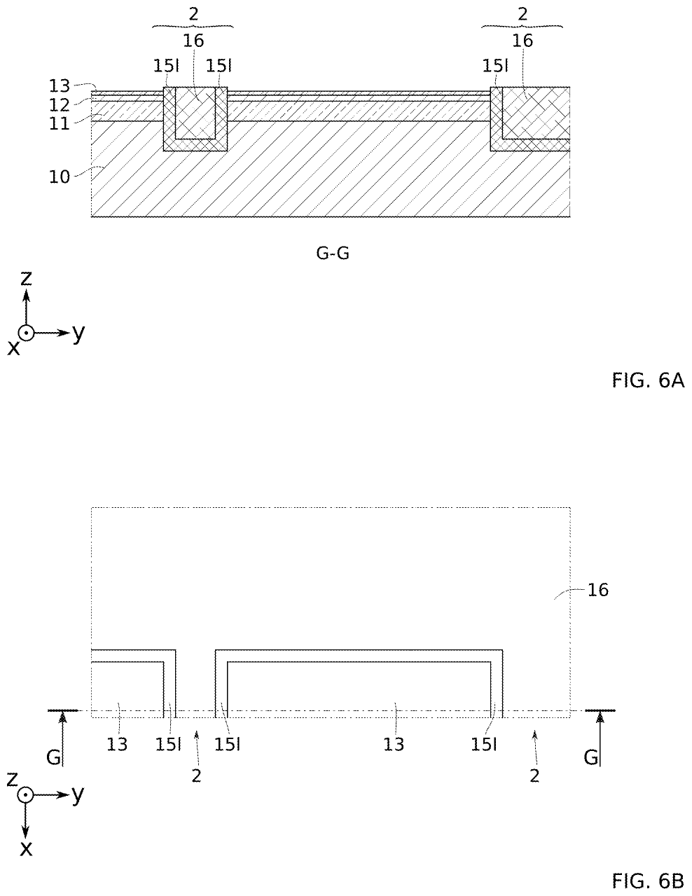

As illustrated in FIGS. 6A, 6B, the residual hard mask film 14r is then selectively removed with respect to the layer 13, the isolating material 16 and preferably with respect to the exposed portions 15l, for example in wet chemistry of the H₃PO₄ type.

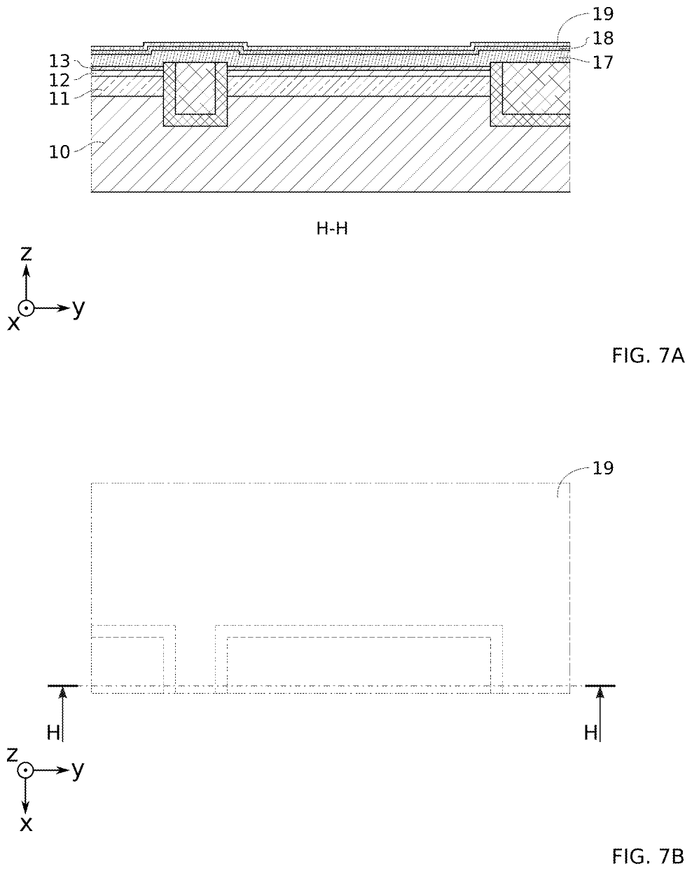

As illustrated in FIGS. 7A, 7B, a standard gate stack is then formed, comprising for example, the oxide layer 13 and/or a so-called “high k” layer at high dielectric constant, a conductive layer 17, for example made of polycrystalline silicon (polySi) and/or made of metal (TiN), surmounted by a hard mask typically comprising an SiN-based layer 18 and an SiO₂-based layer 19.

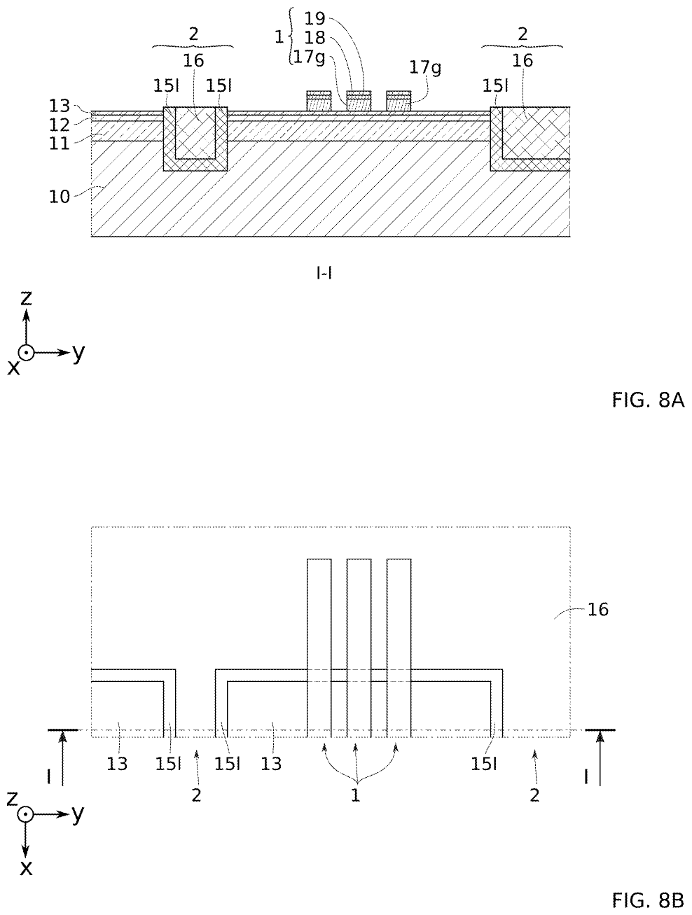

As illustrated in FIGS. 8A, 8B, after definition by lithography of gate patterns 1, and structuring of the hard mask, an anisotropic etching along z of the gate stack is performed. The gate patterns 1 typically comprise a gate 17g surmounted by the hard mask 18, 19. At this stage, the oxide film 13 protects the underlying topSi layer 12.

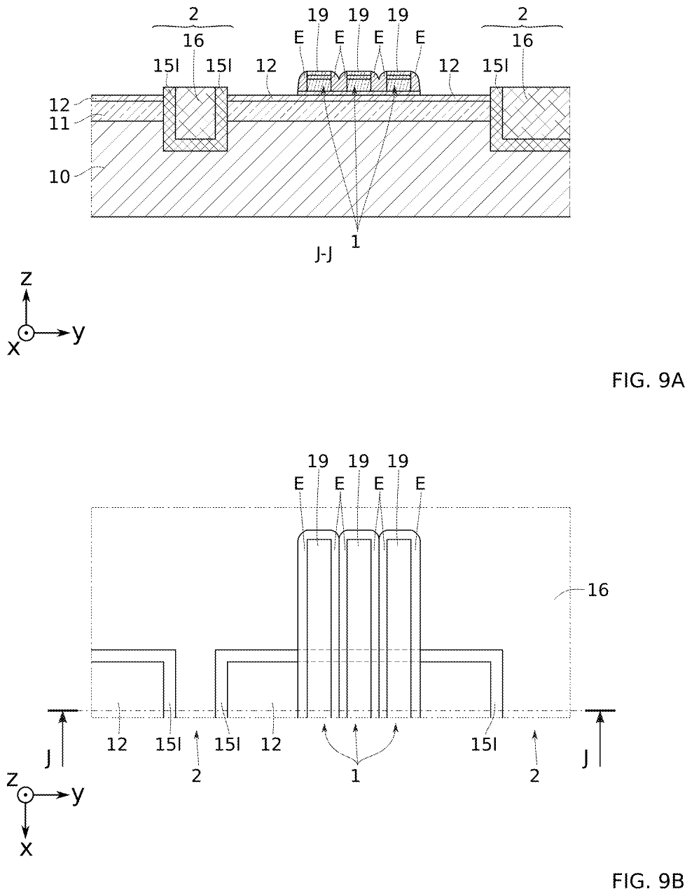

As illustrated in FIGS. 9A, 9B, spacers E are then formed on the flanks of the gate patterns 1, by compatible deposition, then dry etching of a layer with the basis of a known spacer dielectric such as SiO₂, SiN, SiBCN, SiOCN, SiCO, etc. For a quantum application, the thickness of this layer is preferably defined to fill the space between the adjacent gates 17g. For a conventional microelectronic application, the thickness of this layer can be chosen arbitrarily and leave unfilled spaces, in particular to enable a subsequent resumption of contacts on the topSi layer 12, between the gates 17g. The dimension along y of the spacers E is, for example, around 30 nm for an inter-gate space of 60 nm. The layer 13 is then removed around the spacers E, so as to expose the topSi layer 12.

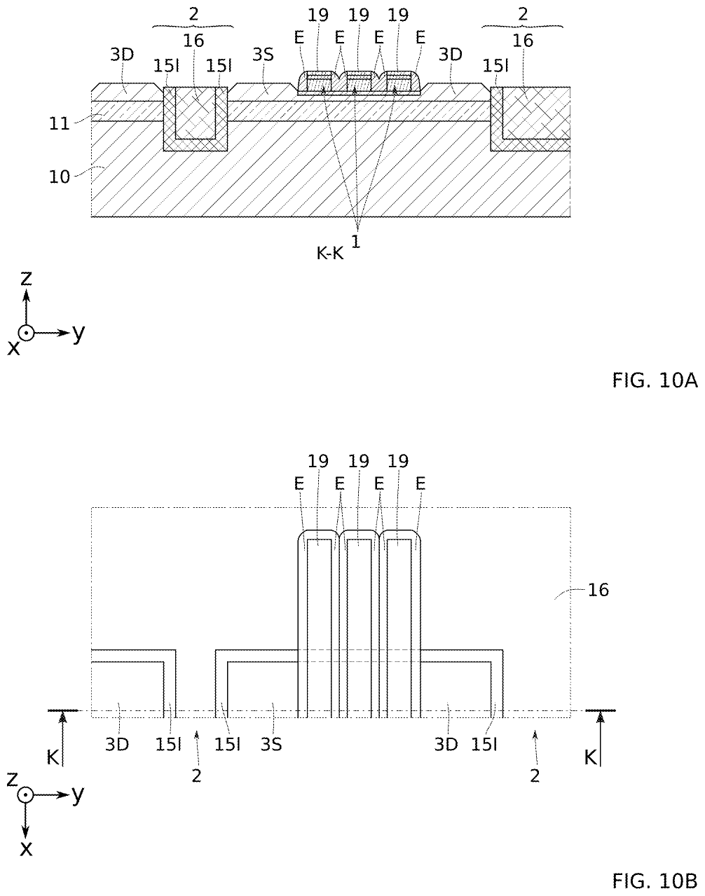

As illustrated in FIGS. 10A, 10B, source and drain regions 3S, 3D, or reservoirs for quantum devices, can be formed by epitaxy on the parts of the exposed topSi layer 12. These regions 3S, 3D are typically doped in situ during epitaxy. They can be phosphorus doped silicon Si:P- or boron doped silicon-germanium SiGe:B-based, for example.

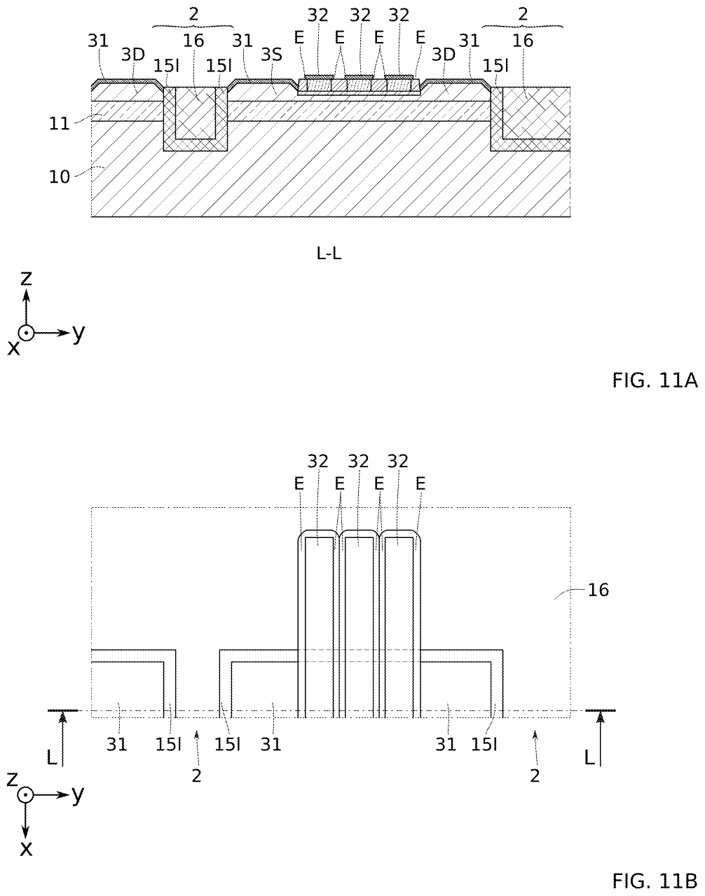

As illustrated in FIGS. 11A, 11B, the hard mask covering the top of the gates 17g is removed before implementing a silicidation method configured to form silicided portions 31, 32, for example, NiPtSi(Ge)-based, at the top of the regions 3S, 3D and of the gates 17g.

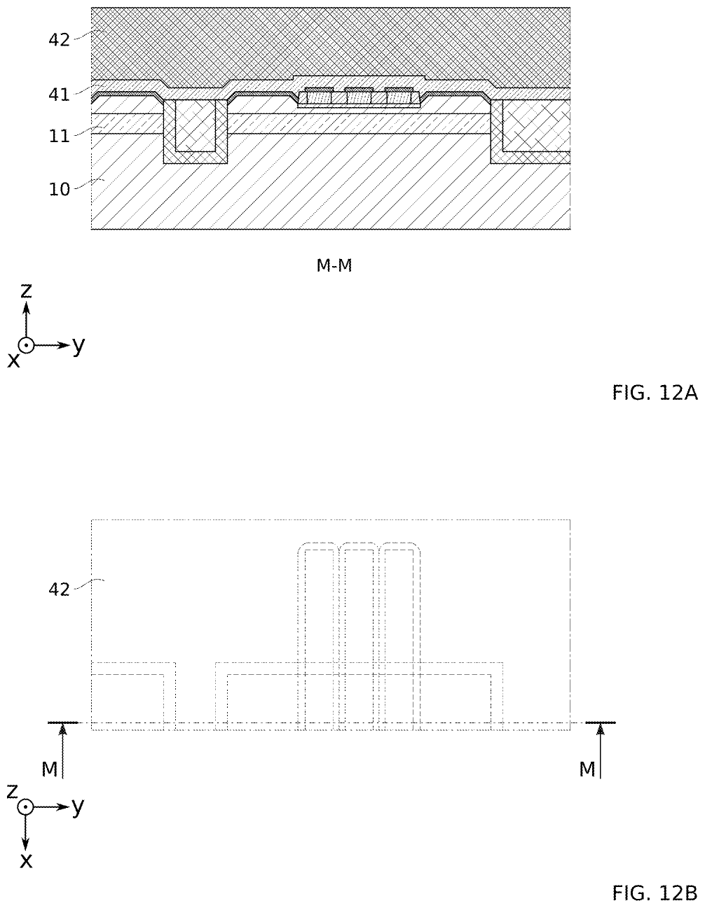

As illustrated in FIGS. 12A, 12B, a compatible deposition of a contact etch stop layer (CESL) 41, for example, made of SiN of thickness e₄₁ of around 30 nm, is first performed. This deposition can be done according to a plasma-enhanced chemical vapour deposition PECVD method. A pre-metallic dielectric (PMD) material 42 deposition, for example, SiO₂-based, is then performed. This deposition can be done according to a known HDP, HARP (high aspect ratio process), FCVD deposition, or from TEOS (tetraethyl orthosilicate)-type precursors. The layer 42 is then planarised by CMP.

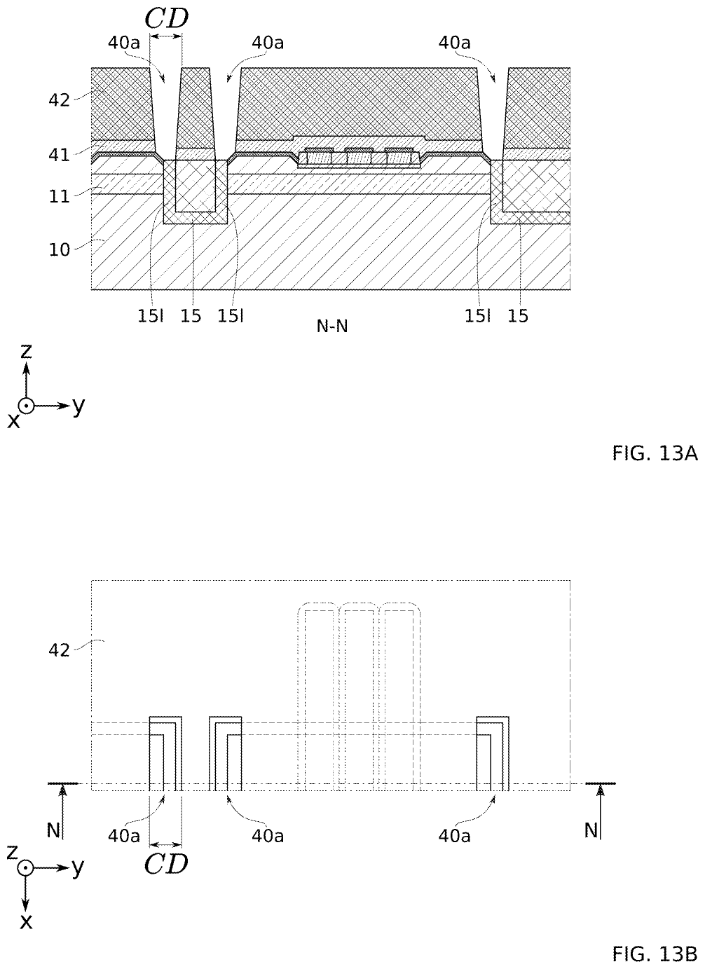

As illustrated in FIGS. 13A, 13B, openings 40a are then made in the layer 42 and the layer 41, by successive dry etchings, in vertical alignment with the portions 15l of the sacrificial coating layer of the isolation trenches STI. Advantageously, the lateral dimension CD along y of the openings 40a is greater than or equal to the thickness e₁₅ of the sacrificial coating layer 15, 15l.

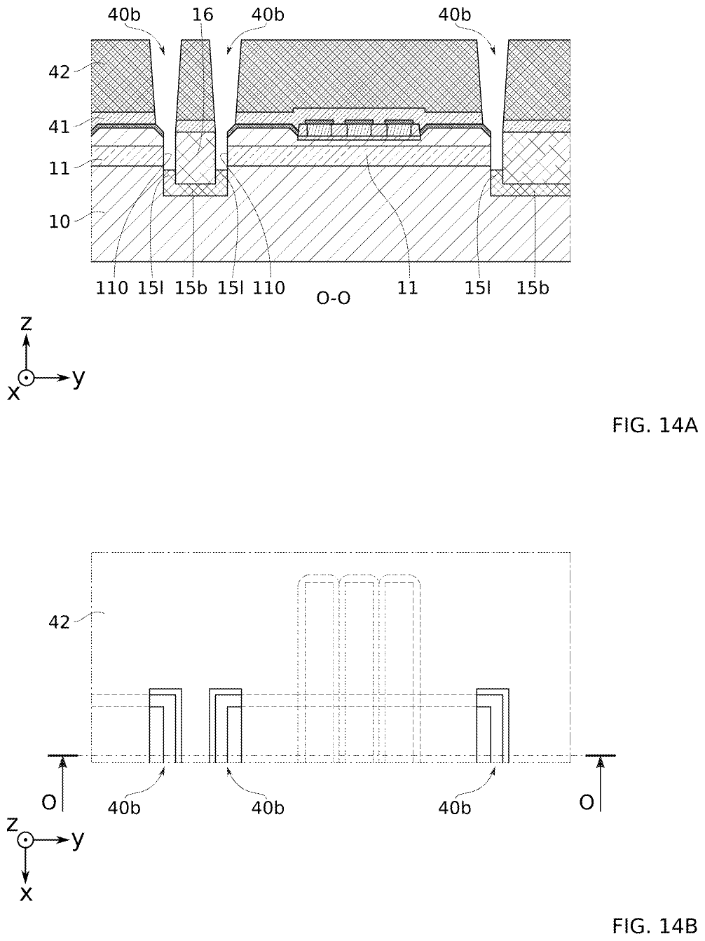

As illustrated in FIGS. 14A, 14B, a partial selective etching of the sacrificial coating layer 15, 15l is then performed through the openings 40a so as to form openings 40b opening onto the flanks 110 of the sacrificial layer 11. The partial etching is preferably configured to totally discover the flanks 110 of the sacrificial layer 11. In this example, the partial etching is stopped so as to preserve at least partially the basal portions 15b of the sacrificial coating layer 15, so as to preserve the mechanical strength of the core 16 in the isolation trenches. Lower parts of the lateral portions 15l of the sacrificial coating layer 15, located under the flanks 110, can also be preserved to improve the mechanical strength. In this example, the sacrificial coating layer 15 is with the basis of a dielectric material, for example, SiN or SIC, to ensure the electric isolation function with the core 16. The partial selective etching is done dry, preferably. In the case of SiN, a wet etching with the basis of a phosphoric acid solution H₃PO₄ can also be implemented.

According to another non-illustrated option, in the case of alternative isolation trenches obtained according to the variant of the method illustrated in FIGS. 4D, 4E, the selective etching of the sacrificial coating layer 15 can be total. These alternative isolation trenches indeed have no basal portions of the sacrificial coating layer 15, and the isolating core 16 rests directly on the bottom 22 of the trench patterns. The stopping of the etching is, in this case, facilitated. Moreover, it is possible to use a conductive material, for example, polySi, for the sacrificial coating layer 15 in the case of these alternative isolation trenches. The core 16 alone is, in this case, able to ensure the electric isolation function of the alternative isolation trenches. The total selective etching can be done wet, for example from a tetramethylammonium hydroxide TMAH solution for polySi.

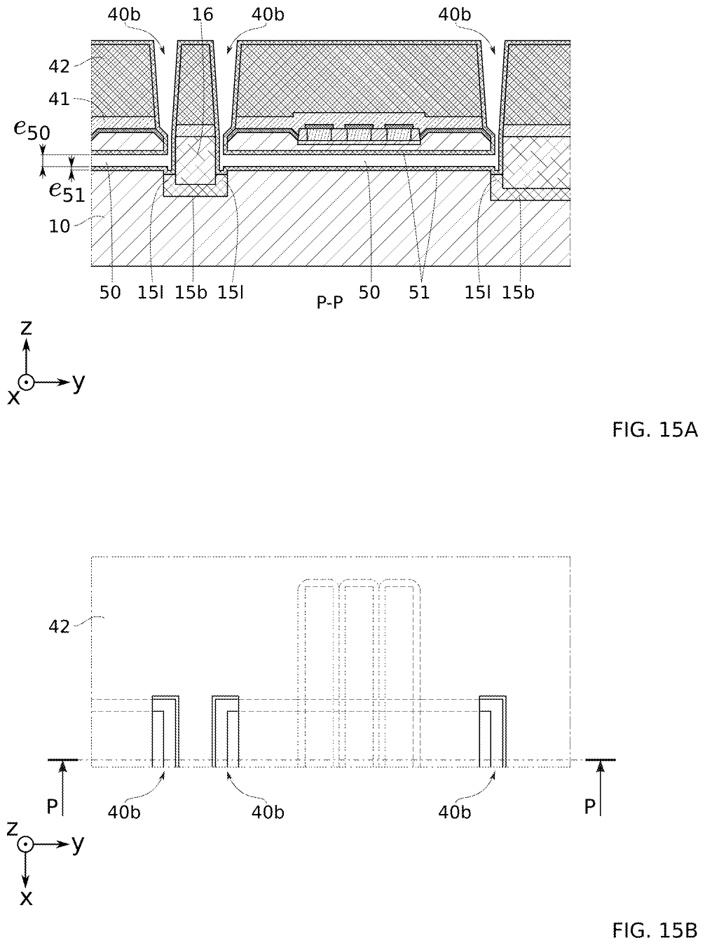

As illustrated in FIGS. 15A, 15B, a selective wet etching of the sacrificial layer 11 with respect to the support and topSi layers 10, 12 and with respect to the cores 16, is performed through the openings 40b. In the case of an SiGe sacrificial layer 11 and of silicon layers 10, 12, a selective etching can be obtained from a hydrochloric acid HCl solution or an HF:H₂O₂:CH₃COOH mixture.

After removal of the sacrificial layer 11, the walls of the cavity 50 are coated by a layer 51 made of a dielectric material, for example, SiN or SiO₂, so as to electrically isolate the future back gate with respect to the support 10 and the topSi 12 layer. This layer 51 preferably has a thickness e₅₁ of between 2 nm and 10 nm. It can be formed by a compatible deposition method of the plasma-enhanced chemical vapour deposition PECVD or of the low-pressure chemical vapour deposition LPCVD or PEALD (plasma-enhanced atomic layer deposition) type. The cavity 50 thus has a height e₅. The sizing rules are preferably such that e₅₁<e₁₅/3 and e₅₁<e₅/3, and preferably such that e₅₁<e₁₅/4 and e₅₁<e₅/4. This makes it possible to preserve sufficiently large opening sections, between the openings 40b and the cavity 50 to enable the subsequent filling with a conductive material.

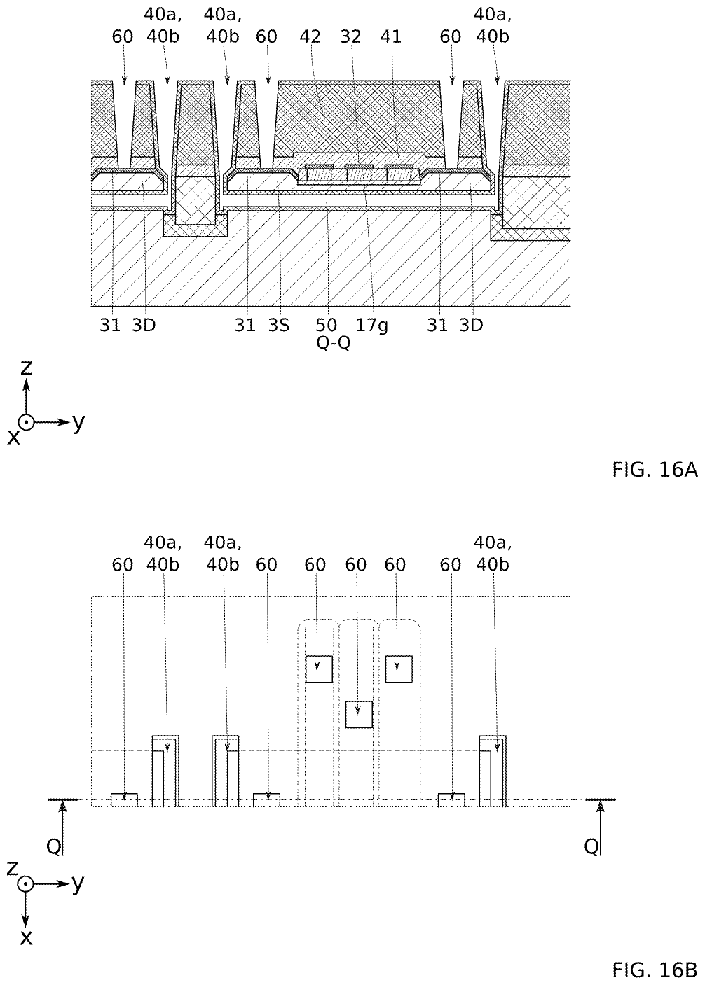

As illustrated in FIGS. 16A, 16B, contact openings 60 are then made in the layers 42, 41, in vertical alignment with the silicided portions 31 of the regions 3S, 3D, and in vertical alignment with the silicided portions 32 of the gates 17g. These contact openings 60 can be made in the same way as the openings 40a. In particular, during the definition of contacts by lithography, the openings 40a are typically blocked by the lithography layer(s) (not illustrated). This makes it possible to not damage the openings 40a during the formation of the contact openings 60.

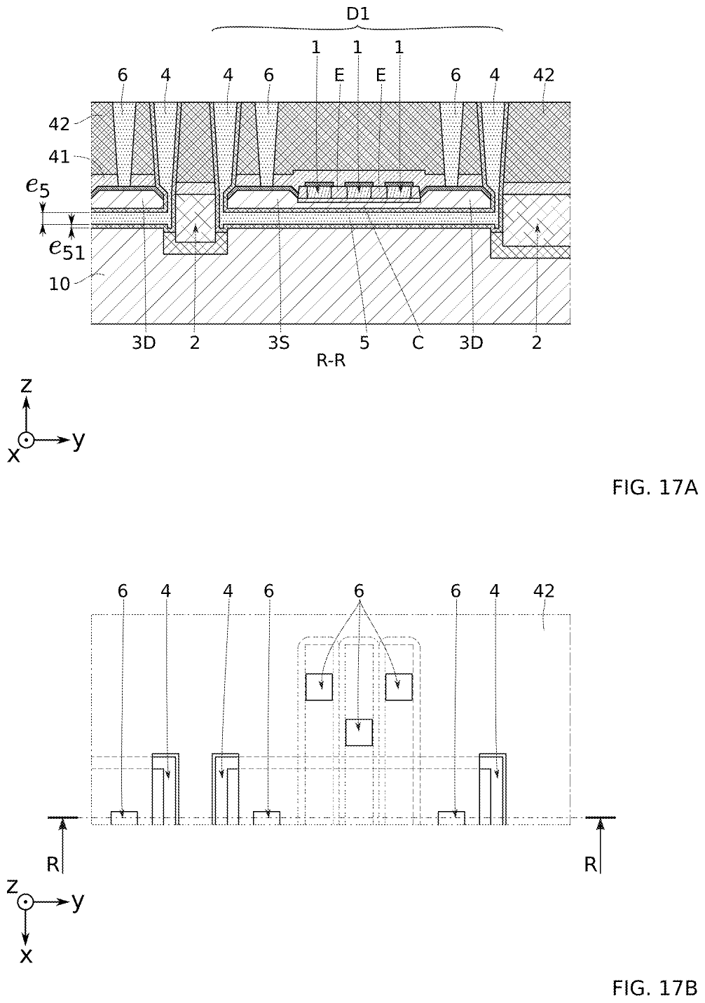

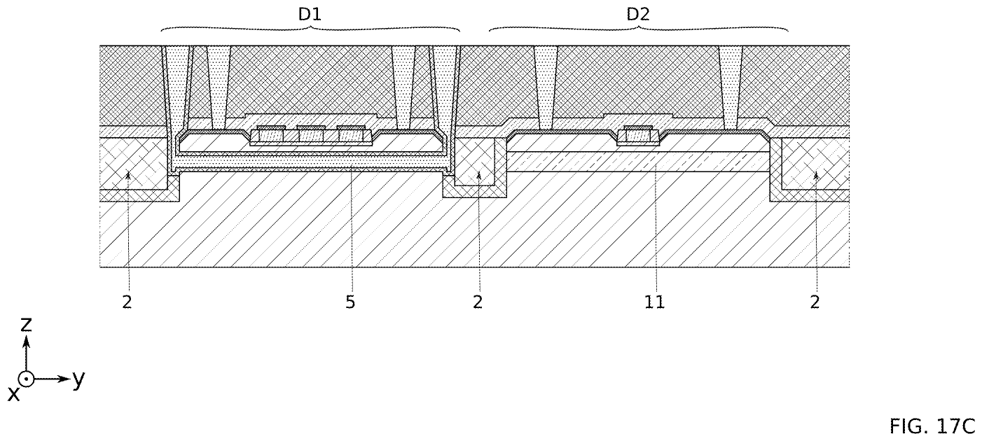

As illustrated in FIGS. 17A, 17B, one or more depositions of metal materials are performed to fill the cavities 50, the openings 40a, 40b and the contact openings 60 simultaneously. A combination of metals such as Ti/TiN/W is, for example, used. Preferably, a CVD method is used to ensure the compatibility of the metal deposition on the walls of the cavity 50. A device D1 comprising gate patterns 1 on a semiconductive layer or a channel C, reservoirs or source and drain regions 3S, 3D, back gate contacts 4 and a back gate 5 under the gate patterns 1 and the channel C, and contacts 6 is thus obtained. This device D1 is electrically isolated with respect to adjacent devices by the isolation trenches 2. The adjacent devices can be similar or identical to the device D1. Back gates 5 are thus formed simultaneously for several adjacent devices which are isolated from one another, thanks to the method according to the invention.

According to an option illustrated in FIG. 17C, the method according to the invention also makes it possible to form a back gate 5 on one single device D1, without forming a back gate on the device D2 adjacent to the device D1. This option of implementation is done without modifying the sizing of the isolation trenches 2, which preserves a good integration or co-integration density of the devices D1, D2. Typically, it is sufficient to form openings 40a, 40b only in vertical alignment with the lateral portions of the sacrificial coating layer located in the immediate proximity of the device requiring a back gate. Thus, only the sacrificial layer located under the device D1 is removed to form the back gate 5. The adjacent device D2, which can be of a different nature (for example, a simple MOSFET transistor) or have a different logic function, is advantageously not affected by the formation of the back gate 5 under the device D1.

In view of the description above, it clearly appears that the method proposed offers a particularly effective and versatile solution to form a back gate under a semiconductive device, by preserving or by improving the integration density of this semiconductive device.

The invention is not limited to the embodiments described above.

1. A method for producing a back gate under a semiconductive device, said semiconductive device being formed on a semiconductive layer of a stack successively comprising a support layer, a sacrificial layer and the semiconductive layer, said method comprising:
a formation of isolation trenches around the semiconductive device, said isolation trenches passing through the superficial semiconductive layer and the sacrificial layer, and extending to the support layer,
a partial etching of the isolation trenches so as to form an opening opening onto the sacrificial layer,
a removal of the sacrificial layer selectively at the semiconductive layer, at the support layer and at the isolation trenches, so as to form a cavity under the semiconductive device, and
a filling of the cavity with an electrically conductive material, so as to form the back gate under the semiconductive device,
wherein the formation of the isolation trenches comprises:
a first etching configured to form at least one trench pattern having a bottom and flanks,
a formation of a sacrificial coating layer at least on the flanks of the at least one trench pattern, in contact with the sacrificial layer of the stack, and
a filling of the at least one trench pattern with an isolating material, configured such that said isolating material extends at least to within the sacrificial layer of the stack, and preferably to within the support layer of the stack, and
the partial etching of the isolation trenches comprises a removal of the sacrificial coating layer selectively at the isolating material.

2. The method according to claim 1, wherein the semiconductive device is a quantum device, and wherein the electrically conductive material is metal.

3. The method according to claim 1, wherein the semiconductive device is adjacent to a second semiconductive device separated from the semiconductive device by an isolation trench having a first flank on the side of the semiconductive device and a second flank on the side of the second semiconductive device, said isolation trench comprising a first sacrificial coating layer portion on the first flank and a second sacrificial coating layer portion on the second flank, and
wherein the partial etching of said isolation trench comprises a simultaneous removal of the first and second sacrificial coating layer portions, so as to form a first back gate under the semiconductive device and a second back gate under the second semiconductive device.

4. The method according to claim 1, wherein the semiconductive device is adjacent to a second semiconductive device separated from the semiconductive device by an isolation trench having a first flank on the side of the semiconductive device and a second flank on the side of the second semiconductive device, said isolation trench comprising a first sacrificial coating layer portion on the first flank and a second sacrificial coating layer portion on the second flank, and
wherein the partial etching of said isolation trench comprises a removal of the first sacrificial coating layer portion only, without removal of the second sacrificial coating layer portion, so as to form the back gate only under the semiconductive device, by preserving a sacrificial layer portion under the second semiconductive device.

5. The method according to claim 1, wherein the formation of the sacrificial coating layer is done by compatible deposition on the flanks and the bottom of the at least one trench pattern.

6. The method according to claim 5, wherein the removal of the sacrificial coating layer is only partial and configured to preserve a portion of the sacrificial coating layer located on the bottom of the at least one trench pattern.

7. The method according to claim 1, wherein the formation of the sacrificial coating layer comprises a compatible deposition on the flanks and the bottom of the at least one trench pattern, followed by an anisotropic etching configured to remove a portion of the sacrificial coating layer located on the bottom of the at least one trench pattern, such that the sacrificial coating layer only covers the flanks of the at least one trench pattern, before filling the at least one trench pattern with the isolating material.

8. The method according to claim 7, wherein the removal of the sacrificial coating layer is total.

9. The method according to claim 1, wherein the sacrificial coating layer is chosen with the basis of a first dielectric material, for example, SiN or SiC.

10. The method according to claim 1, wherein the formation of the sacrificial coating layer is configured, such that the sacrificial coating layer has a thickness e15 in a direction transverse to the flanks of the at least one trench pattern, and the filling of the at least one trench pattern with the isolating material is configured such that the isolating material has a thickness e16 in said transverse direction, such that e15<e16/3.

11. The method according to claim 1, further comprising, after removal of the sacrificial layer and before filling the cavity with an electrically conductive material, a compatible deposition of a layer made of a second dielectric material on exposed walls of the cavity, for example, by chemical vapour deposition (CVD).

12. The method according to claim 11, wherein the layer made of a second dielectric material has a thickness e51, the sacrificial coating layer has a thickness e15, the electrically conductive material has a thickness e5, such that e51<e15/3 and e51<e5/3, and preferably such that e51<e15/4 and e51<e5/4.

13. The method according to claim 1, wherein the isolating material of the isolation trenches is chosen with the basis of SiO₂.

14. The method according to claim 1, wherein the sacrificial layer is formed on the support layer by epitaxy, said sacrificial layer being SiGe-based.

15. A semiconductive device comprising a back gate made by a method for producing a back gate according to claim 1.

16. The semiconductive device according to claim 15, wherein said semiconductive device is a quantum device, and wherein the electrically conductive material is metal.
